(19) United States
(12) Patent Application Publication
(10) Pub. No.: US 2010/0071768 A1
(43) Pub. Date: Mar. 25, 2010

(54) ENHANCED SOLAR COLLECTOR

(75) Inventor: TAI HUI LIU, Hsinchu County 303 (TW)

Correspondence Address: HAMRE, SCHUMANN, MUELLER & LARSON, P.C., P.O. BOX 2902, MINNEAPOLIS, MN, 55402-0902, US

(73) Assignee: SOLAPOINT CORPORATION, Hsinchu County 303 (TW)

(21) Appl. No.: 12/237,763

(22) Filed: Sep. 25, 2008

(51) Int. Cl. H01L 31/052

(52) U.S. Cl. 136/259

(57) ABSTRACT

An enhanced solar collector is provided in this invention, wherein a through hole is formed in a secondary mirror in Cassegrain system, and a light collecting device focusing lights, originally shaded by the secondary mirror, via the through hole to increase light-collecting efficiency of the enhanced solar collector.

### BACKGROUND OF THE INVENTION

1. Field of the Invention

The present invention is generally related to a solar collecting system, and more particularly to an enhanced solar collecting system and solar power generator.

2. Description of the Prior Art

Energy generated from solar cell is commonly known as a better and clean energy than other power resources, such as fossil fuel power, nuclear energy power, or hydraulic power. Solar power can be much more superior when the continuing inflation of crude oil. Further, oil is bound to exhaust soon or later, but the solar power, on the other side, is exhaustless power resources compared to petrifaction power. Hence, many governments, research/development units, and private enterprises put numerous research resources into the solar power industry.

For high material cost of photovoltaic cell, and in order to cost down such that solar power can be commercialized and popular to staple commodity, now a method is provided to use optical concentrating system to reduce high material cost of using solar cell. The simplest way is to use relative large area of lens to collect lights such that a larger area of lights can be concentrated into a relative smaller area of photovoltaic cell to increase power generating efficiency. Nevertheless, due to mass volume and weight of lens, cumbersome solar power generating system is incurred. Furthermore, issues come from conventional lens optical system, such as aberration, chromatic aberration, or focus, can be raised also. Therefore, some research topics turn to other optical concentrating system to solve the issues above mentioned.

One solution, provided by Fork and Maeda that uses Cassegrain system as solar collecting system to concentrate lights, can solve the issues above mentioned. The solution they provide can be referred to US Pub. No. 2006/0231133, wherein a primary mirror and a secondary mirror are used to collect lights into photovoltaic cell. Moreover, a transparent dielectric material, such as glass or resin, can be configured between the primary mirror and secondary mirror to increase power efficiency of photovoltaic cell. Detailed description can be referred to Concentrator Photovoltaics, edited by Antonio Luque and Viacheslav Andreev, published by Springer. A relative small solar power generating system and more power generating efficiency can be obtained throughout such design.

On the other hand, a series of studies focused on improvement of Cassegrain solar concentrating system are published by Solfocus and Palo Alto Research Center. For example, please refer to a PCT publication WO 2006/130520, a plurality of small solar power generating system is assembled in an array, and a sensor is used to track solar trace such that the array can trace direction and location of the sun to gain the best power generating efficiency. In another PCT publication WO 2007/130794, a thick copper film is used as thermal dissipating means in solar power generating system. The operating temperature can be decreased significantly for long exposure to sunlight. Particularly to semiconductor device like photovoltaic cell, the higher the operating temperature is, the less conversion efficiency of photon-to-electricity is. In WO 2007/130795, a vacuum lamination technology is used to print circuits directly into optical device and hence no other PCB is used to decrease whole volume. And, a resilient package structure is used for photovoltaic cell as shown in a different PCT publication WO 2007/130796.

None of the technologies recited above solves an issue comes from Cassegrain system; that is the secondary mirror does block a portion of light. It is not important for a telescope because the blocked lights by the secondary mirror do not material as long as celestial body in distance can be imaged. Nevertheless, in solar concentrating system, the blocked light can not be used to generate power; that means a portion of power generating efficiency is sacrificed. Please refer to FIG. 1, a photovoltaic cell 130 is located at the bottom region of a primary mirror 110, and a secondary mirror 120 is over the primary mirror 110. After lights are reflected by the primary mirror 110 to the secondary mirror 120 and through a second reflection of the secondary mirror 120, reflected lights forward to photovoltaic cell 130. However, a portion of area 150 on the secondary mirror 120 can not be radiated to any light. The authors of Concentrator Photovoltaics also mention this issue on page 115. Hence, an improved structure is necessary to solve the issue so that the blocked lights by the secondary mirror can be utilized to recover sacrificial power generating efficiency.

### SUMMARY OF THE INVENTION

According to the issues raised from prior art and accommodating to requirement of industrial benefit, this invention provides an enhanced solar collecting system by using Cassagrain system, wherein a primary mirror with a concave surface corresponding to a secondary mirror with convex surface, and a light collecting device above the secondary mirror. A through hole is located at the center of the secondary mirror, where the lights originally blocked by the secondary mirror can be concentrated or collected by the light collecting device then into the through hole.

One object of this invention is to resolve lowered solar power generating efficiency from the secondary mirror blocking lights in Cassagrain optical system.

Another object of this invention is to enhance radiation utility to promote power generating efficiency.

### BRIEF DESCRIPTION OF THE DRAWINGS

FIG. 1 illustrates a cross-sectional structure view of a traditional Cassagrain solar concentrating system;

FIG. 2 illustrates a cross-sectional structure view of a through hole formed on the secondary mirror of a solar collecting system according to this invention;

FIG. 3 illustrates a cross-sectional structure view of a light collecting device allocated above the secondary mirror of a solar collecting system according to this invention;

FIG. 4 illustrates a cross-sectional structure view of a Fresnel lens allocated above the secondary mirror of a solar collecting system according to this invention;

FIG. 5 illustrates a cross-sectional structure view of an upper tapered optical rod allocated above the secondary mirror of a solar collecting system according to this invention;

FIG. 6 illustrates a cross-sectional structure view of an aperture lens allocated in the through hole of the secondary mirror of a solar collecting system according to this invention;

FIG. 7 illustrates a cross-sectional structure view of a lower tapered optical rod allocated on the photovoltaic cell of a solar collecting system according to this invention;

FIG. 8 illustrates a cross-sectional structure view of combining a Fresnel lens and an aperture lens according to this invention;

FIG. 9 illustrates a cross-sectional structure view of combining a condensing lens, an aperture lens and a lower tapered optical rod according to this invention;

FIG. 10 illustrates a cross-sectional structure view of combining an upper tapered optical rod and an aperture lens according to this invention; and

FIG. 11 illustrates a cross-sectional structure view of combining an upper tapered optical rod, an aperture lens and a lower tapered optical rod according to this invention.

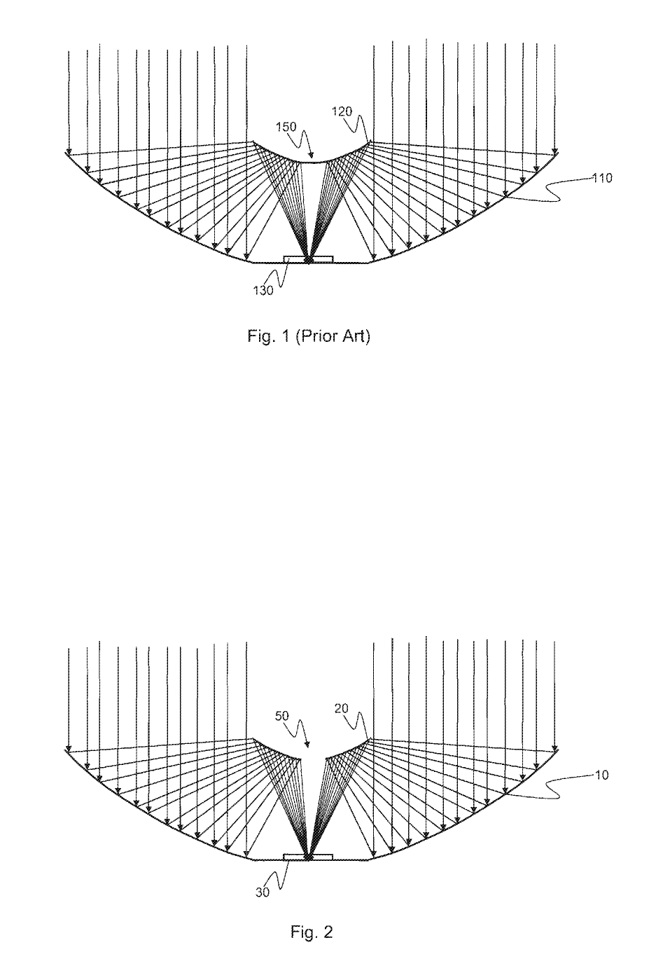

### DESCRIPTION OF THE PREFERRED EMBODIMENTS

What is probed into the invention is an enhanced solar collector and a solar power generating system. Detailed descriptions of the structure and elements will be provided in the following in order to make the invention thoroughly understood. Obviously, the application of the invention is not confined to specific details familiar to those who are skilled in the art. On the other hand, the common structures and elements that are known to everyone are not described in details as to avoid unnecessary limits of the invention.

This invention exploits a through hole formed in a secondary mirror or a convex mirror and a light collecting device or means for collecting light blocked by the secondary or convex mirror to generate power.

Due to the light blocked by the secondary mirror is about 5% of the primary mirror's aperture, thus the 5% of light shall be utilized to generate more power in this invention, and the solar power generating efficiency can be enhanced therefore.

This invention provides an enhanced solar collector, which comprises a primary mirror with an upward concave surface, a secondary mirror with a downward convex surface above the primary mirror, wherein center of the secondary mirror has a through hole, and a light collecting device over the secondary mirror to collect lights shaded by the secondary mirror, that blocks the aperture surface of the primary mirror, into the through hole.

The light collecting device can be a first lens, a Fresnel lens, or an upper tapered optical rod. The enhanced solar collector further comprises a second lens within the through hole. Moreover, this invention comprises a transparent dielectric material between the primary mirror and the secondary mirror, and a lower tapered optical rod beneath the through hole.

An enhanced solar concentrating system is also provided, which comprises a first mirror with an upward concave surface to concentrate light, a second mirror with a downward convex surface over the first mirror to reflect light concentrated by the first mirror to a photovoltaic cell on the bottom region of the concave surface of the first mirror, wherein the central region of the second mirror has a through hole, and means for collecting light shaded by the second mirror to pass the shaded light, via the through hole, to the photovoltaic cell. The means for collecting light is over the second mirror.

The size of the through hole is about the first mirror's incident lights shaded by the second mirror and reflected from the first mirror onto the second mirror. A lens is located in the through hole to concentrate the shaded light, via the through hole, into the photovoltaic cell. The enhanced solar concentrating system further comprises a light collecting device beneath the second mirror to concentrate the light through the through hole into the photovoltaic cell, wherein the light-collecting device can be a tapered optical rod.

A solar collecting system is provided, which comprises a solid transparent optical element, a primary mirror, a secondary mirror, and a light collecting device. The solid transparent optical element comprises a first part having a relative large concave surface, and a second part having a planar light-incident surface and being opposite to the first part, wherein the central portion of the light-incident surface has a relative small convex surface. The primary mirror is located at the concave surface, and the secondary mirror is located at the convex surface, wherein the central portion of the secondary mirror has a through hole. The light collecting device is above the secondary mirror for collecting lights shaded by the secondary mirror, via the through hole, into the solid transparent optical element. The light collecting device can be a first lens (for example, condensers), a Fresnel lens, or an upper tapered optical rod. The solar collecting system further comprises a second lens (for example, condensers) within the through hole, and a lower tapered optical rod beneath the solid transparent optical element.

The invention further provides a solar power generator, which comprises a photovoltaic cell, and a solar collecting system. The solar collecting system comprises a primary mirror with an upward concave surface, a secondary mirror with a downward convex surface above the primary mirror and the central portion thereof having a through hole, and a light collecting device above the secondary mirror to collect lights shaded by the secondary mirror, that blocks the aperture surface of the primary mirror, into the through hole. The photovoltaic cell is located on the bottom region of the upward concave surface.

The light collecting device can be a first lens (for example, condensers), a Fresnel lens, or an upper tapered optical rod. The solar power generator further comprises a second lens (for example, condensers) within the through hole. Moreover, this invention comprises a transparent dielectric material between the primary mirror and the secondary mirror, and a lower tapered optical rod placed beneath the through hole.

Next, please refer to the drawings to set forth detail, features and embodiments of this invention.

Please refer to FIG. 2, a first mirror 10, as a convex primary mirror, having a photovoltaic cell 30 located on the bottom region of the first mirror 10, and a second mirror 20, as s concave secondary mirror is configured above the first mirror 10. The primary mirror 10 and the secondary mirror 20 correspond with each other such that lights from aperture surface of the primary mirror 10 radiating to the primary mirror 10 are firstly reflected to the secondary mirror 20. Then, lights are secondly reflected through the secondary mirror 20 into the photovoltaic cell 30. In this invention, a through hole 50 is formed in the secondary mirror 20, wherein the size of the through hole 50 is about the primary mirror's incident lights shaded by the secondary mirror 20 and reflected from the primary mirror 10 onto the secondary mirror 20. Method for formatting the through hole 50 can be mechanical drilling to the secondary mirror 20.

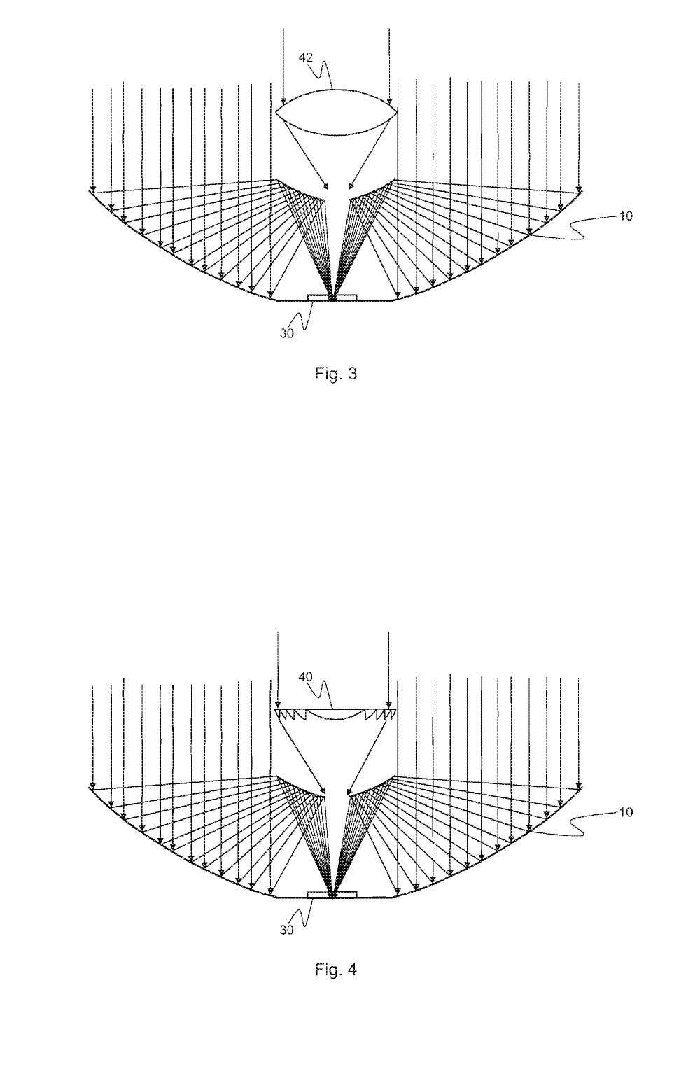

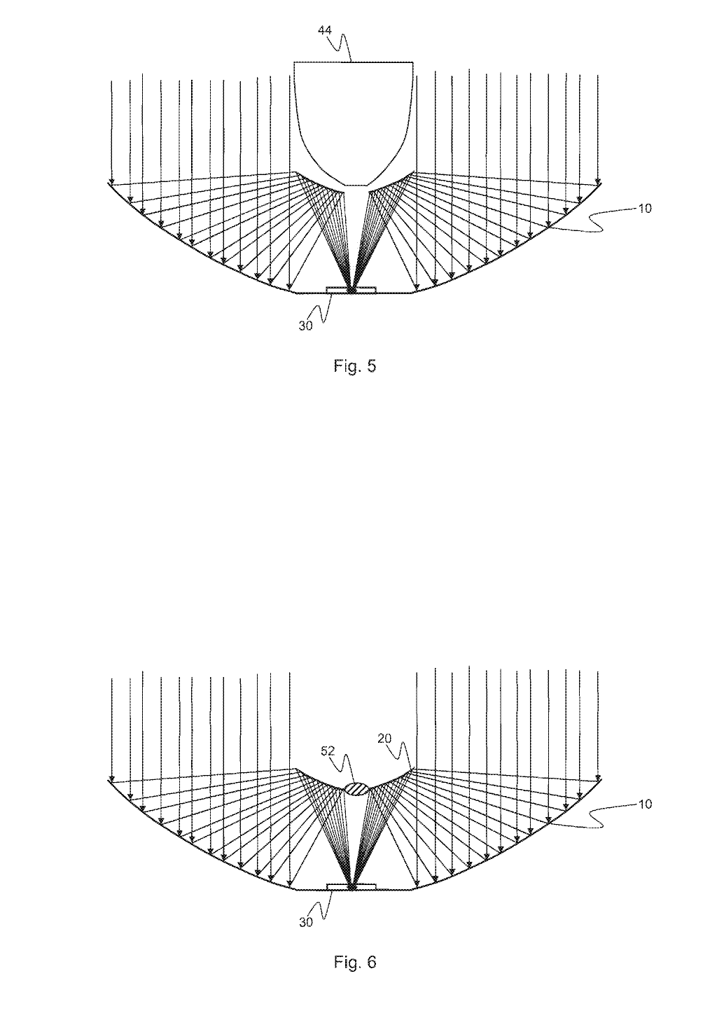

In order to focus the blocked lights by the secondary mirror 20 into the through hole 50, a light collecting device shall be configured above the secondary mirror 20. One embodiment can be referred to FIG. 3, a lens (for example, condensers) 42 can be used as one kind of light collecting device to collect light blocked by the secondary mirror 20 into the through hole 50. Another embodiment can be referred to FIG. 4, a Fresnel lens 40 is used as light collecting device to collect light blocked by the secondary mirror 20 into the through hole 50. Still another embodiment can be referred to FIG. 5, an upper tapered optical rod 44 can be used as light collecting device to collect light blocked by the secondary mirror 20 into the through hole 50. The upper tapered optical rod 44 is an optical element that can generate total internal reflection to collect larger area of lights into a smaller area. Material of the upper tapered optical rod 44 can be transparent material with high refractive index to increase possibility of total internal reflection, and lights collected by tapered optical rod are reflected to the bottom thereof. Glass and quartz are commonly available materials.

Because the through hole 50 corresponding to the light collecting device is optical aperture, not all of lights gathered by the light collecting device can be radiated to the photovoltaic cell 30. One embodiment, as shown in FIG. 6, an aperture lens 52 is configured inside the through hole 50. While focus length of the aperture lens 52 is configured, lights should be focused into the photovoltaic cell 30. After the light collecting device is configured, utility of light blocked by the secondary mirror 20 can be increased. Therefore, a plurality of embodiments can be applied between light collecting device and aperture lens 52.

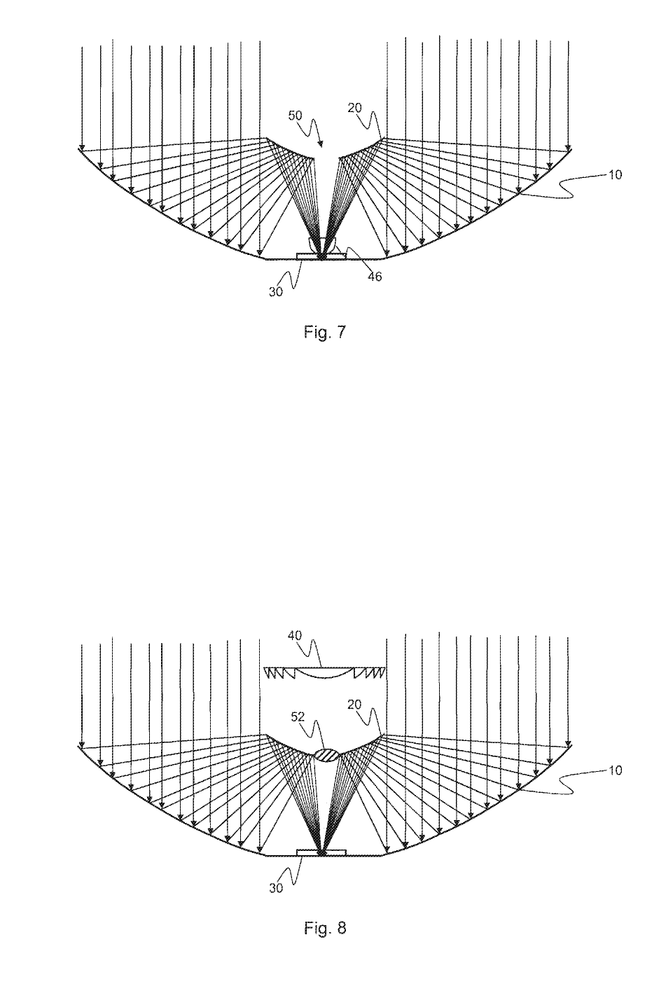

Another tapered optical rod can be allocated over the photovoltaic cell 30 to collect all light. Please referred to FIG. 7, a lower tapered optical rod 46 is used to collect lights from the through hole 50 and reflected by the secondary mirror 20 into the photovoltaic cell 30.

This invention can possibly be all combinations and portfolios by all means mentioned above. The following paragraphs merely take a portion of types explained with drawings, but not to limit embodiments of this invention to these types. Any kind of embodiment of combination or portfolio shall be construed to scope of this invention.

Please referred to FIG. 8, a Fresnel lens 40 and an aperture lens 52 are combined. Because optical effect of a Fresnel lens is equivalent to normal condensing lens, a normal condensing lens can be also used to replace Fresnel lens therefore. A benefit of using Fresnel lens is to decrease thickness of optical element.

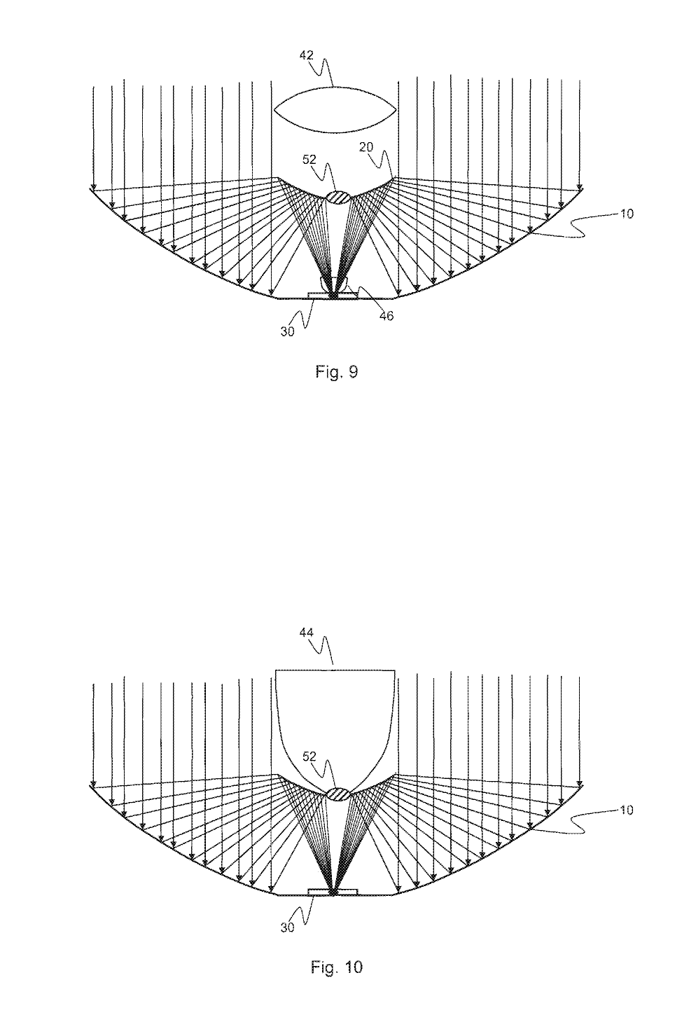

Please referred to FIG. 9, a condensing lens 42, an aperture lens 52, and a tapered optical rod 46 are used. Similarly, the condensing lens can be replaced by a Fresnel lens in this embodiment.

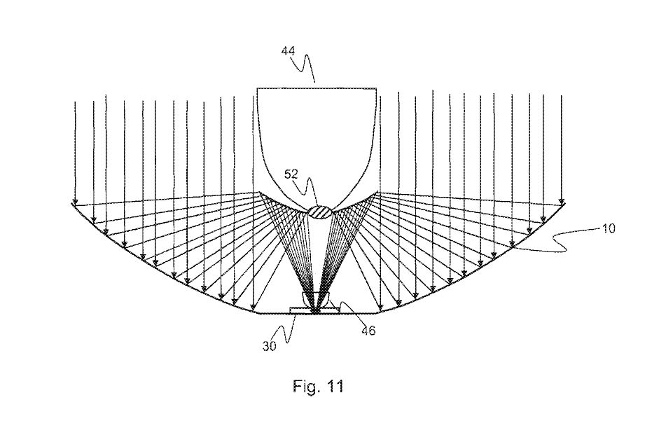

Please referred to FIG. 10, an upper tapered optical rod 44 and an aperture lens 52 are combined as another embodiment. Moreover, please referred to FIG. 11, an upper tapered optical rod 44, an aperture lens 52, and a lower tapered optical rod 46 are used as a further embodiment. Two tapered optical rods are used in this embodiment to completely use all lights blocked by the secondary mirror 20.

Further, a transparent dielectric material can be filled between the primary mirror 10 and the secondary mirror 20, wherein the transparent dielectric material can be high light transmittance material, such as glass, transparent resin, or acrylic. In this embodiment, a solid transparent optical element is formed first, wherein comprises a first part having a relative large concave surface, and a second part having a planar light-incident surface and being opposite to the first part, wherein the central portion of the light-incident surface has a relative small convex surface. The primary mirror 10 is allocated on the first surface, while the secondary mirror 20 is allocated on the small convex surface.

Power generating efficiency can be upgraded by means of this invention, because lights blocked by the secondary mirror can be used to generate power. Issues mentioned above then can be resolved by this invention.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. An enhanced solar collector, comprising:
a primary mirror with an upward concave surface;
a secondary mirror with a downward convex surface above said primary mirror, wherein the center of said secondary mirror has a through hole; and
a light collecting device above said secondary mirror to collect lights shaded by said secondary mirror, that blocks the aperture surface of said primary mirror, into said through hole.

2. The enhanced solar collector according to claim 1, wherein said light collecting device can be a first lens, a Fresnel lens, or an upper tapered optical rod.

3. The enhanced solar collector according to claim 2, further comprising a second lens within said through hole.

4. The enhanced solar collector according to claim 3, further comprising a transparent dielectric material between said primary mirror and said secondary mirror.

5. The enhanced solar collector according to claim 1, further comprising a transparent dielectric material between said primary mirror and said secondary mirror.

6. The enhanced solar collector according to claim 3, further comprising a lower tapered optical rod beneath said second lens.

7. The enhanced solar collector according to claim 1, further comprising a lower tapered optical rod beneath said through hole.

8. The enhanced solar collector according to claim 1, wherein the size of said through hole is about the area of said first mirror's incident lights shaded by said second mirror and reflected from said first mirror onto said second mirror.

9. A solar collecting system, comprising:
a solid transparent optical element, comprising:
a first part having a relative large concave surface; and
a second part having a planar light-incident surface and being opposite to said first part, wherein the central portion of said planar light-incident surface has a relative small convex surface;
a primary mirror located at said concave surface;
a secondary mirror locate at said convex surface, wherein the central portion of said secondary mirror has a through hole; and
a light collecting device above said secondary mirror for collecting lights shaded by said secondary mirror, via said through hole, into said solid transparent optical element.

10. The solar collecting system according to claim 9, wherein said light collecting device can be a first lens, a Fresnel lens, or an upper tapered optical rod.

11. The solar collecting system according to claim 10, further comprising a second lens located inside said through hole.

12. The solar collecting system according to claim 9, further comprising a lower tapered optical rod beneath said solid transparent optical element.

13. The solar collecting system according to claim 9, wherein the size of said through hole is about the area of said first mirror's incident lights shaded by said second mirror and reflected from said first mirror onto said second mirror.

14. A solar power generator, comprising:
a photovoltaic cell; and
a solar collecting system, comprising:
a primary mirror with an upward concave surface, wherein the bottom region of said upward concave surface being located said photovoltaic cell;
a secondary mirror with a downward convex surface above said primary mirror, wherein the central portion of said secondary mirror has a through hole; and
a light collecting device above said secondary mirror to collect lights shaded by said secondary mirror, that blocks the aperture surface of said primary mirror, into said through hole.

15. The solar power generator according to claim 14, wherein said light collecting device can be a first lens, a Fresnel lens, or an upper tapered optical rod.

16. The solar power generator according to claim 15, further comprising a second lens located inside said through hole.

17. The solar power generator according to claim 16, further comprising a transparent dielectric material between said primary mirror and said secondary mirror.

18. The solar power generator according to claim 14, further comprising a transparent dielectric material between said primary mirror and said secondary mirror.

19. The solar power generator according to claim 16, further comprising a lower tapered optical rod beneath said second lens.

20. The solar power generator according to claim 14, further comprising a lower tapered optical rod beneath said through hole.
